(19) United States
(12) Patent Application Publication
(10) Pub. No.: US 2014/0268984 A1
(43) Pub. Date: Sep. 18, 2014

(54) SEMICONDUCTOR DEVICE AND ELECTRONIC APPARATUS

(71) Applicant: SONY CORPORATION, Tokyo (JP)

(72) Inventor: Yuki Yanagisawa, Kanagawa (JP)

(73) Assignee: SONY CORPORATION, Tokyo (JP)

(21) Appl. No.: 14/182,312

(22) Filed: Feb. 18, 2014

(30) Foreign Application Priority Data
Mar. 15, 2013 (JP) 2013-052705

(51) Int. Cl. G11C 17/16; H01L 23/525

(52) U.S. Cl. CPC G11C 17/16; H01L 23/5252
USPC 365/96; 257/530

(57) ABSTRACT

Provided is a semiconductor device that includes: a storage element including a first terminal, a second terminal, and a third terminal, and in which a resistance state between the second terminal and the third terminal is changed from a high resistance state to a low resistance state based on a stress current that flows between the first terminal and the second terminal; and a fuse connected to the first terminal, and configured to change from a conductive state to a non-conductive state based on the stress current.

### CROSS REFERENCE TO RELATED APPLICATIONS

This application claims the benefit of Japanese Priority Patent Application JP 2013-052705 filed on Mar. 15, 2013, the entire contents of which are incorporated herein by reference.

### BACKGROUND

The present disclosure relates to a semiconductor device that includes an anti-fuse, and an electronic apparatus that includes such a semiconductor device.

A nonvolatile memory that allows information saving even after a power source has been turned off is frequently integrated in an electronic apparatus. An example of such a nonvolatile memory includes an OTP (One Time Programmable) memory that data writing into it is allowed only one time. For example, trimming information used to adjust characteristics and so forth of a circuit may be stored in such a memory. Thus, in the electronic apparatus, it is allowed to implement desired characteristics by performing adjustment of the characteristics and so forth of the circuit on the basis of the trimming information stored in that memory directly after the power source has been turned on.

An anti-fuse is frequently used as a storage element in such a memory. The anti-fuse is configured such that a resistance value thereof is reduced by being applied with a stress current. Memories each using such an anti-fuse are disclosed, for example, in Japanese Unexamined Patent Application Publication (Published Japanese Translation of PCT Application) No. JP2006-510203 and Japanese Unexamined Patent Application Publication No. 2012-174863.

### SUMMARY

In general, it is desired for a memory to be formed with small area and further miniaturization is expected.

It is desirable to provide a semiconductor device and an electronic apparatus that allow implementation of miniaturization.

According to an embodiment of the present disclosure, there is provided a semiconductor device including: a storage element including a first terminal, a second terminal, and a third terminal, and in which a resistance state between the second terminal and the third terminal is changed from a high resistance state to a low resistance state based on a stress current that flows between the first terminal and the second terminal; and a fuse connected to the first terminal, and configured to change from a conductive state to a non-conductive state based on the stress current.

According to an embodiment of the present disclosure, there is provided another semiconductor device including: a plurality of memory cells; and a control circuit configured to control the plurality of memory cells. Each of the memory cells includes: a storage element including a first terminal, a second terminal, and a third terminal, and in which a resistance state between the second terminal and the third terminal is changed from a high resistance state to a low resistance state based on a stress current that flows between the first terminal and the second terminal; a fuse connected to the first terminal, and configured to change from a conductive state to a non-conductive state based on the stress current; and a selecting transistor connected to the third terminal.

According to an embodiment of the present disclosure, there is provided an electronic apparatus including: a storage element including a first terminal, a second terminal, and a third terminal, and in which a resistance state between the second terminal and the third terminal is changed from a high resistance state to a low resistance state based on a stress current that flows between the first terminal and the second terminal; a fuse connected to the first terminal, and configured to change from a conductive state to a non-conductive state based on the stress current; and a control circuit configured to control the storage element and the fuse.

In the semiconductor devices and the electronic apparatus according to the above-described embodiments of the present disclosure, the resistance state between the second terminal and the third terminal of the storage element is changed from the high resistance state to the low resistance state on the basis of the stress current that flows between the first terminal and the second terminal of the storage element so as to store information. At that time, the fuse is changed from the conductive state to the non-conductive state on the basis of that stress current.

According to the semiconductor devices and the electronic apparatus in the above-described embodiments of the present disclosure, since the fuse is connected to the first terminal of the storage element, implementation of miniaturization is possible.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a block diagram illustrating one configuration example of a semiconductor device according to an embodiment of the present disclosure.

FIG. 2 is a circuit diagram illustrating one configuration example of a memory cell array illustrated in FIG. 1.

FIG. 3 is a circuit diagram illustrating one configuration example of a memory cell illustrated in FIG. 2.

FIG. 4 is a sectional diagram illustrating one example of an essential part sectional structure of the memory cell illustrated in FIG. 3.

FIG. 5 is a plan view illustrating one configuration example of a fuse illustrated in FIG. 3.

FIG. 6 is a sectional diagram illustrating one configuration example of a conductive film, a contact, and a wiring illustrated in FIG. 5.

FIG. 7 is a flowchart illustrating one example of a writing operation.

FIG. 8 is a circuit diagram schematically illustrating one example of one state of the writing operation.

FIG. 9 is a circuit diagram schematically illustrating one example of another state of the writing operation.

FIG. 10 is a sectional diagram illustrating an example of a filament.

FIG. 11 is a circuit diagram schematically illustrating one example of a further state of the writing operation.

FIG. 12 is a circuit diagram schematically illustrating one example of a still further state of the writing operation.

FIG. 13 is a circuit diagram schematically illustrating one example of one state of a reading operation.

FIG. 14 is a circuit diagram illustrating one configuration example of a memory cell array according to a comparative example.

FIG. 15 is a circuit diagram schematically illustrating one example of one state of a writing operation according to the comparative example.

FIG. 16 is a circuit diagram schematically illustrating one example of one state of a reading operation according to the comparative example.

FIG. 17 is a circuit diagram schematically illustrating one example of a still further state of the writing operation.

FIG. 18 is a sectional diagram illustrating one example of an essential part sectional structure of a memory cell according to one modification example.

FIG. 19 is a sectional diagram illustrating another example of an essential part sectional structure of a memory cell according to another modification example.

FIG. 20 is a plan view illustrating one configuration example of a fuse according to a further modification example.

FIG. 21 is a plan view illustrating another configuration example of the fuse according to the further modification example.

FIG. 22 is a sectional diagram illustrating a further configuration example of the fuse according to the further modification example.

FIG. 23 is a perspective view illustrating one example of an external configuration of a television set to which the semiconductor device according to any of the embodiments and the like is applied.

FIG. 24 is a circuit diagram illustrating one example of a delay adjustment circuit to which the semiconductor device according to any of the embodiments and the like is applied.

### DETAILED DESCRIPTION

In the following, an embodiment of the present disclosure will be described in detail with reference to the accompanying drawings. It is to be noted that description will be made in the following order.

### 1. Embodiment

### 2. Application Examples

### 1. Embodiment

### Configuration Examples

### General Configuration Example

FIG. 1 illustrates one configuration example of a semiconductor device according to an embodiment of the present disclosure. A semiconductor device 1 is a storage in which an anti-fuse is used as a storage element. The semiconductor device 1 includes a memory cell array 10, a write word line drive section 11, a bit line drive section 12, a read word line drive section 13, and a sense amplifier 14.

The memory cell array 10 includes a plurality of memory cells 20 that are arranged in a matrix. In addition, the memory cell array 10 includes a plurality of write word lines WL1 and a plurality of read word lines WL2 that extend in a row direction (a lateral direction), and a plurality of bit lines BL and a plurality of source lines SL that extends in a column direction (a longitudinal direction). One end of each write word line WL1 is connected to the write word line drive section 11 and one end of each read word line WL2 is connected to the read word line drive section 13. In addition, one end of each bit line BL is connected to the bit line drive section 12 and one end of each source line SL is connected to the sense amplifier 14.

FIG. 2 illustrates one configuration example of the memory cell array 10. FIG. 3 illustrates a configuration example of the memory cell 20. Each memory cell 20 is connected to the write word line WL1, the read word line WL2, the bit line BL, and the source line SL. The memory cell 20 includes a storage element 21, a selecting transistor 22, and a fuse 23.

The storage element 21 is a storage element that functions as an anti-fuse and includes three terminals. This storage element 21 has the same configuration as an N type MOS (Metal Oxide Semiconductor) transistor. In the following, description will be made by using the names of three terminals (a drain, a gate, and a source) of the MOS transistor as the three terminals of the storage element 21 for the convenience of description. A drain of the storage element 21 is connected to the bit line BL, a gate thereof is connected to one end of the fuse 23, and a source thereof is connected to a drain of the selecting transistor 22. This storage element 21 is configured such that a resistance state between the drain and the source is changed from the high resistance state into the low resistance stage by applying a stress voltage VST between the gate and the drain so as to store information in accordance with a change in this resistance state.

The selecting transistor 22 is an N type MOS transistor, the drain thereof is connected to the source of the storage element 21, a gate thereof is connected to the read word line WL2, and a source thereof is connected to the source line SL. The fuse 23 is configured such that its electric state is changed from a short-circuited state (a conductive state) into an open-circuited (a non-conductive state) with a stress current IST, and one end thereof is connected to the gate of the storage element 21 and the other end thereof is connected to the write word line WL1.

Owing to this configuration, in the memory cell 20, a dielectric film 131 (described later) of the storage element 21 is broken down by applying the stress voltage VST between the gate and the drain of the storage element 21 and thus a current flows in a writing operation as described later. Then, a filament F is formed between the drain and the source of the storage element 21 with heat generated by that current, and the resistance state is changed and thus information is stored in the storage element 21. At that time, the fuse 23 is put into the open-circuited state with the current caused by breakdown of the dielectric film 131. That is, the current caused by the breakdown of the dielectric film 131 serves as the stress current IST for the fuse 23. This avoids flowing of an unnecessary current between the gate of the storage element 21 in which the information is written and the write word line drive section 11 as described later.

FIG. 4 illustrates one example of an essential part sectional structure of the memory cell 20. The memory cell 20 is formed on a single semiconductor substrate 100P by using a general CMOS (Complementary Metal Oxide Semiconductor) manufacturing process. The storage element 21 and the selecting transistor 22 of the memory cell 20 are formed in a region surrounded with an element separation section 114.

The memory cell 20 includes semiconductor layers 110P, and 111N to 113N, dielectric films 131 and 133, conducive films 132 and 134, and electrodes 141 and 142.

The semiconductor layer 110P is a P type semiconductor layer disposed within the semiconductor substrate 100P, and configures a so-called P-well. This semiconductor layer 110P functions as a so-called back gate of the storage element 21 and the selecting transistor 22. This semiconductor layer 110P is made of a semiconductor material in which impurities such as boron (B) and so forth are doped into silicon (Si). It is to be noted that a 0V-voltage is being applied to the semiconductor layer 110P via a not illustrated contact.

The semiconductor layers 111N, 112N, and 113N are N type semiconductor layers (so called N+ layers) disposed within the semiconductor layer 110P. The semiconductor layer 111N and the semiconductor layer 112N are separately disposed leaving a predetermined space between them. The semiconductor layer 112N and the semiconductor layer 113N are separately disposed leaving a predetermined space between them. The semiconductor layer 111N corresponds to the drain of the storage element 21. The semiconductor layer 112N corresponds to the source of the storage element 21 and also corresponds to the drain of the selecting transistor 22. The semiconductor layer 113N corresponds to the source of the selecting transistor 22. Each of these semiconductor layers 111N, 112N, and 113N may be made of a semiconductor material in which impurities such as, for example, arsenic (As), phosphorus (P) and so forth are doped into silicon, and its thickness may be about 50 nm to about 200 nm both inclusive. These semiconductor layers 111N, 112N, and 113N may be readily formed by, for example, a technique by self-alignment or a technique using mask patterns of photoresists, oxide films and so forth. It is desirable to reduce a distance (a separation interval L1) between the semiconductor layer 111N and the semiconductor layer 112N as much as possible. Specifically, for example, it may have a minimum processing size in its manufacturing process. Alternatively, it may be preferable to make it shorter than the minimum processing size within a range that the semiconductor layer 111N and the semiconductor layer 112N are normally formed separately from each other. Thus, it is allowed to reduce the element size of the storage element 21 and it is allowed to more readily form the later described filament F. In addition, it is desirable to make a distance (a separation interval L2) between the semiconductor layer 112N and the semiconductor layer 113N longer than the separate interval L1. Thus, it is allowed to reduce a possibility that a filament which is similar to that in the storage element 21 may be formed on the selecting transistor 22.

Parts of the respective semiconductor layers 111N, 112N, and 113N are silicided. Specifically, a silicided part 121 is the one that a part of the semiconductor layer 111N has been silicided, a silicided part 122 is the one that a part of the semiconductor layer 112N has been silicided, and a silicided part 123 is the one that a part of the semiconductor layer 113N has been silicided. These silicided parts 121 to 123 may be the ones formed by a siliciding process used in a general manufacturing process by using, for example, cobalt (Co), nickel (Ni) and so forth. The silicided parts 121 to 123 are the ones formed in order to reduce resistance values of the semiconductor layers 111N, 112N, and 113N. In addition, parts of the respective silicided parts 121 to 123 melt with heat caused by the breakdown of the dielectric film 131 to form the filament F in the writing operation as described later. That is, the material of each of the silicided parts 121 to 123 has a melting point that it would partially melt with that heat.

The dielectric film 131 is formed on the semiconductor layer 110P in a region between the semiconductor layer 111N and the semiconductor layer 112N and on parts of the respective semiconductor layers 111N and 112N. The dielectric film 133 is formed on the semiconductor layer 110P in a region between the semiconductor layer 112N and the semiconductor layer 113N and on parts of the respective semiconductor layers 112N and 113N similarly. These dielectric films 131 and 133 may be made of, for example, silicon oxides (such as SiO₂) and so forth and the thickness thereof may be about several nm to about 20 nm both inclusive.

The conductive film 132 is formed on a region where the dielectric film 131 is formed. This conductive film 132 corresponds to the gate of the storage element 21. The conductive film 134 is formed on a region where the dielectric film 133 is formed. This conductive film 134 corresponds to the gate of the selecting transistor 22. Each of the conductive films 132 and 134 may be made of a conductive material such as, for example, polycrystalline silicon, a silicided metal and so forth and the thickness thereof may be about 50 nm to about 500 nm both inclusive. It is to be noted that the conductive films 132 and 134 are connected to wirings so as to allow application of voltages to the conductive film 132 (the gate of the storage element 21) and the conductive film 134 (the gate of the selecting transistor 22) via these wirings as described later.

An insulating layer 150 is so disposed as to cover the semiconductor substrate 100P, the semiconductor layers 111N to 113N, the conductive films 132 and 134 and so forth. The insulating layer 150 may be made of an insulating material such as, for example, a silicon oxide and so forth, and the thickness thereof may be about 50 nm to 1000 nm both inclusive.

An electrode 141 is so disposed on the semiconductor layer 111N as to be electrically connected with this semiconductor layer 111N. This electrode 141 is so formed as to pass through the insulating layer 150 and is connected to a wiring 151 disposed on the insulating layer 150. This wiring 151 is led to the bit line BL. An electrode 142 is so disposed on the semiconductor layer 113N as to be electrically connected with this semiconductor layer 113N similarly. This electrode 142 is so formed as to pass through the insulating layer 150 and is connected to a wiring 152 disposed on the insulating layer 150. This wiring 152 is led to the source line SL. The electrodes 141 and 142 may be made of, for example, tungsten (W), and the wirings 151 and 152 may be made of, for example, aluminum (Al). Thus, it is allowed to apply voltages to the respective semiconductor layers 111N (the drain of the storage element 21) and 113N (the source of the selecting transistor 22) in the memory cell 20. In addition, parts of the respective electrodes 141 and 142 melt with heat caused by the breakdown of the dielectric film 131 so as to form the filament F in the writing operation as described later. That is, the material of each of the electrodes 141 and 142 has a melting point that it would partially melt with that heat.

Owing to this configuration, the semiconductor layers 111N, 112N, the dielectric film 131, and the conductive film 132 configure the storage element 21, and the semiconductor layers 112N and 113N, the dielectric film 133, and the conductive film 134 configure the selecting transistor 22 in the memory cell 20.

FIG. 5 is a plan view illustrating one example of the memory cell 20. FIG. 6 illustrates one example of a sectional configuration of the memory cell 20 illustrated in FIG. 5 viewed in a direction of an arrow V-V. The conductive film 132 extends in a direction of a channel width (W) of the storage element 21 and is connected to a wiring 155 via a contact 145 on the outer side of the storage element 21. The conductive film 134 extends in a direction of a channel width (W) of the selecting transistor 22 and is connected to a wiring 154 via a contact 144 on the outer side of the selecting transistor 22 similarly. The contacts 144 and 145 may be made of, for example, tungsten (W) and the wirings 154 and 155 may be made of, for example, aluminum (Al) similarly to the wirings 151 and 152.

The conductive film 132 includes a part (a narrowed part 160) which is narrower in width than the conductive film 132 of the storage element 21 between the storage element 21 and the contact 145. The narrowed part 160 configures the fuse 23 and an electric state of the fuse 23 is changed from the short-circuited state (the conductive state) to the open-circuited state (non-conductive state) by making the stress current IST of a predetermined value flow through it. Specifically, the width of the conductive film 132 on the narrowed part 160 is a width that the narrowed part 160 is changed into the open-circuited state when a current of a value equal to or higher than a minimum current value which is necessary to form the filament F between the drain and the source of the storage element 21 has flown. Thus, the fuse 23 is configured to be disconnected so as to be changed into the open-circuited state after the filament F has been formed on the storage element 21. As described above, the fuse 23 has a simple structure and is allowed to be implemented with small area.

In FIG. 1, the write word line drive section 11 is adapted to control the writing operation in the memory cell 10 by driving the write word line WL1. Specifically, the write word drive section 11 is configured to select one row (one word) including a memory cell 20 to be subjected to the writing operation by setting a voltage VWL1 of the write word line WL1 to a negative voltage VM (VM<0).

The bit line drive section 12 is adapted to control the writing operation in the memory cell 10 by driving the bit line BL. Specifically, the bit line drive section 12 is configured to select a memory cell 20 to be subjected to the writing operation in the selected one row by setting a voltage VBL of the bit line BL to a positive voltage VP (VP>0).

Owing to this configuration, the negative voltage VM is applied to the gate by the write word line drive section 11 and the positive voltage VP is applied to the drain by the bit line drive section 12 in the storage element 21 of the memory cell 20 to be subjected to the writing operation. Thus, the stress voltage VST (=VP+|VM|) is applied between the gate and the drain of that storage element 21. This stress voltage VS is set to a voltage value that allows breakdown of the dielectric film 131 and formation of the filament F between the drain and the source. Thus, the breakdown of the dielectric film 131 and the formation of the filament F are made possible without generating an inversion layer on the semiconductor substrate 100P under the conductive film 132.

The semiconductor device 1 is configured to generate the stress voltage VST using the two voltages VP and VM in the semiconductor device 1 in the above-mentioned case. Thus, it is allowed to configure the transistor of the bit line drive section 12 that generates the voltage VP and the transistor of the write word line drive section 11 that generates the voltage VM by general transistors. That is, for example, if 0V is to be applied to the drain of the storage element 21 and a negative voltage corresponding to the stress voltage VST is to be applied to the gate thereof, there will be cases when it is necessary to configure the transistor of the write word line drive section 11 by a high withstand voltage transistor. In the above-mentioned case, it becomes necessary to add a process for manufacturing the high withstand voltage transistor and, for example, the cost may be increased. Since the semiconductor device 1 is configured to generate the stress voltage VST using the two voltages VP and VM in the semiconductor device 1, it is allowed to more simplify the manufacturing process.

The memory cell 20 is configured to write information into it by forming the filament F between the drain and the source of the storage element 21 as described above.

The read word line drive section 13 is adapted to control a reading operation in the memory cell 10 by driving the read word line WL2. Specifically, the read word line drive section 13 is adapted to select one row (one word) including a memory cell 20 to be subjected to the reading operation by setting a voltage VWL2 of the read word line WL2 to a high level voltage VH.

The sense amplifier 14 is adapted to control the reading operation in the memory cell 10 by driving the source line SL. Specifically, the sense amplifier 14 is adapted to read out information stored in the memory cell 20 to be subjected to the reading operation by setting a voltage VSL of the source line SL to a voltage Vread and detecting a read current tread flowing into the source line SL.

Owing to this configuration, in the memory cell 20 to be subjected to the reading operation, the read transistor 22 enters an ON state and the voltage Vread is applied across the storage element 21 by the sense amplifier 14. Thus, the read current tread according to presence/absence of the filament F between the drain and the source is generated in the storage element 21. That is, since the resistance state between the drain and the source of the storage element 21 is the high resistance state when the filament F is not formed between them, the read current tread is reduced. On the other hand, since the resistance state between the drain and the source of the storage element 21 is the low resistance state when the filament F is formed between them, the read current tread is increased. The sense amplifier 14 is configured to read out the information stored in the memory cell 20 by detecting this read current tread.

Here, the gate of the storage element 21 corresponds to one specific example of a “first terminal” in one embodiment of the present disclosure, the drain of the storage element 21 corresponds to one specific example of a “second terminal” in one embodiment of the present disclosure, and the source of the storage element 21 corresponds to one specific example of a “third terminal” in one embodiment of the present disclosure. The semiconductor layer 110P corresponds to one specific example of a “first semiconductor layer” in one embodiment of the present disclosure. The semiconductor layer 111N corresponds to one specific example of a “second semiconductor layer” in one embodiment of the present disclosure. The semiconductor layer 112N corresponds to one specific example of a “third semiconductor layer” in one embodiment of the present disclosure. The semiconductor layer 113N corresponds to one specific example of a “fourth semiconductor layer” in one embodiment of the present disclosure. The dielectric film 131 corresponds to one specific example of a “first dielectric film” in one embodiment of the present disclosure and the dielectric film 133 corresponds to one specific example of a “second dielectric film” in one embodiment of the present disclosure. The conductive film 132 corresponds to one specific example of a “first conductive film” in one embodiment of the present disclosure and the conductive film 134 corresponds to one specific example of a “second conductive film” in one embodiment of the present disclosure.

### [Operations and Actions]

Operations and actions of the semiconductor device 1 according to the present embodiment will be described subsequently.

### (Summary of General Operation)

First, the summary of the general operation of the semiconductor device 1 will be described with reference to FIG. 1 to FIG. 3. The write word line drive section 11 controls the writing operation in the memory cell array 10 by driving the write word line WL1. The bit line drive section 12 controls the writing operation in the memory cell array 10 by driving the bit line BL. In the memory cell 20 to be subjected to the writing operation, information is written into the memory cell 20 by applying the stress voltage VST between the gate and the drain of the storage element 21 thereof and then forming the filament F between the drain and the source thereof.

The read word line drive section 13 controls the reading operation in the memory cell array 10 by driving the read word line WL2. The sense amplifier 14 controls the reading operation in the memory cell array 10 by driving the source line SL. In the memory cell 20 to be subjected to the reading operation, the selecting transistor 22 enters the ON state and the voltage Vread is applied between the drain and the source of the storage element 21, and therefore the read current Iread according to presence/absence of the filament F is generated. The sense amplifier 14 reads out the information stored in the memory cell 20 by detecting this current.

### (Detailed Operations)

The writing operation to be performed on the memory cell 20 will be described in detail.

FIG. 7 is a flowchart illustrating one example of the writing operation. In this example, a case that the writing operation is to be performed on a memory cell 20 (i, j) that comes i-th in the row direction (the lateral direction) and j-th in the column direction (the longitudinal direction) will be described.

First, the write word line drive section 11 and the bit line drive section 12 apply the stress voltage VST to the memory cell 20 (i, j) to be subjected to the writing operation (step S1).

FIG. 8 schematically illustrates one example of a state of the memory cell array 10 in application of the stress voltage VST. When the stress voltage VST is to be applied to the memory cell 20 (i, j), the write word line drive section 11 sets a voltage VWL (j) of a j-th write word line WL1(j) to the negative voltage VM and the bit line drive section 12 sets a voltage VBL(i) of an i-th bit line BL(i) to the positive voltage VP. For example, the voltage VM may be about −4.5 V and the voltage VP may be about 5V. In that case, both of a voltage VWL2(j) of a j-th read word line WL2(j) and a voltage of an i-th source line SL(i) are set to 0V. Thus, the voltage of the drain of the storage element 21 of the memory cell 20 (i, j) is set to the voltage VP and the voltage of the gate thereof is set to the voltage VM. That is, the stress voltage VST (=VP+|VM|) is applied between the drain and the gate of the storage element 21.

Then, the dielectric film 131 is broken down (step S2). That is, a local electric field intensity of the dielectric film 131 may be increased to a value, for example, on the order of MV/cm or more by applying the stress voltage VST between the drain and the gate of the storage element 21 and the dielectric film 131 is broken down.

FIG. 9 schematically illustrates one example of a state of the memory cell 20 (i, j) after the dielectric film 131 has been broken down. Since when the dielectric film 131 is broken down as illustrated in the drawing, conduction is created between the drain and the gate of the storage element 21, a current I1 of, for example, about several tens mA may flow from the bit line BL (i) to the write word line WL1 (j) via the drain and the fuse 23 of the storage element 21.

Since the electric field intensity in the dielectric film 131 is strong, in particular, in a part (a part P1 in FIG. 4) where the conductive film 312 faces the semiconductor layer 111N, it is through that breakdown occurs in the vicinity thereof. Since, in general, the interface state, the film thickness and the shape of the dielectric film 131 are not thoroughly uniform, the electric field intensity in that part P1 is not uniform and there exists a part which is particularly high in electric field intensity. Therefore, it is thought that the current I1 caused by the breakdown locally flows to the vicinity of such a part which is particularly high in electric field intensity.

Heat is generated by making a large current locally flow as described above and the temperature may be increased to, for example, near about 1000 C.° to about 2000 C.° both inclusive. Thus, the part of the silicided part 121 of the semiconductor layer 111N, the part of the silicided part 122 of the semiconductor layer 112N, and the part of the electrode 141 melt and damage the semiconductor substrate 100P under the dielectric film 131. As a result, the filament F is formed between the semiconductor layer 111N (the drain of the storage element 21) and the semiconductor layer 112N (the source of the storage element 21) (step S3).

FIG. 10 schematically illustrates one example of formation of the filament F. FIG. 11 schematically illustrates one example of a state of the memory cell 20 (i, j) after the filament F has been formed. The filament F is formed such that the semiconductor layer 111N (the drain of the storage element 21) and the semiconductor layer 112N (the source of the storage element 21) are mutually connected to the semiconductor substrate 100P under the dielectric film 131 via a resistance component as illustrated in FIG. 10.

Then, the fuse 23 is disconnected (step S4). That is, the current I1 caused by the breakdown of the dielectric 131 occurred in step S2 flows into the narrowed part 160 (the fuse 23) of the conductive film 132. The width of the narrowed part 160 is set such that it is changed into the open-circuited state when the current of the value equal to or higher than the minimum current value (for example, about 5 mA to about 20 mA both inclusive) which is necessary to form the filament F between the drain and the source of the storage element 21 has flown as described above. Thus, the fuse 23 is disconnected after the filament F has been formed on the storage element 21 and is changed into the open-circuited state.

FIG. 12 schematically illustrates one example of a state of the memory cell array 10 after the fuse 23 has been disconnected. Flowing of the current from the bit line BL (i) to the write word line WL1 (j) of the memory cell 20 (i, j) is stopped by disconnection of the fuse 23.

Thus, the writing operation performed on the memory cell 20 (i, j) is completed.

Next, the reading operation to be performed on the memory cell 20 will be described in detail. In this example, the reading operation to be performed on the memory cell 20 (i, j) that the filament F is formed will be described.

FIG. 13 schematically illustrates one example of a state of the memory cell array 10 when performing the reading operation. When information is to be read out from the memory cell 20 (i, j), the read word line drive section 11 sets the voltage VWL2 (j) of the j-th read word line WL2 (j) to the high level voltage VH. Thus, the selecting transistors 22 of the memory cells 20 of one row including the memory cell 20 (i, j) enter the ON states. Then, the sense amplifier 14 sets the voltage VSL (i) of the i-th source line SL (i) to the positive voltage Vread. The voltage Vread may be, for example, about 0.5 V. At that time, both of the voltage VWL1 (j) of the j-th write word line WL1 (j) and the voltage of the i-th bit line BL (i) are set to 0V. Thus, the voltage Vread is applied between (the filament F) the drain and the source of the storage element 21 of the memory cell 20 (i, j) and the read current Tread according to the resistance component of the filament F is generated in the storage element 21. This read current Tread flows from the source line SL (i) to the bit line BL (i) through the selecting transistor 22 and the storage element 21 (the filament F). The sense amplifier 14 detects this read current Tread and compares it with a predetermined threshold value so as to read out the information stored in the memory cell 20.

It is to be noted that although the reading operation performed on the memory cell 20 (i, j) that the filament F is formed has been described hereinabove, the same also applies to the memory cell 20 that the filament F is not formed. In this case, since the state between the drain and the source of the storage element 21 is the high resistance state, the read current Tread hardly flows. The sense amplifier 14 reads out the information stored in the memory cell 20 by comparing this read current Tread with the predetermined threshold value.

### Comparative Example

Next, a semiconductor device 1R according to a comparative example will be described. This semiconductor device 1R is of a configuration that a memory cell 20R is configured with no provision of the fuse 23. Other configurations are the same as those of the present embodiment (FIG. 1).

FIG. 14 illustrates one configuration example of a memory cell array 10R in the semiconductor device 1R according to the comparative example. In the memory cell array 10R, memory cells 20R are formed in a matrix. The memory cell 20R includes the storage element 21 and the selecting transistor 22. That is, this memory cell 20R is of the type that the fuse 23 is omitted from the memory cell 20 (FIG. 3) according to the present embodiment. In the memory cell 20R, the gate of the storage element 21 is connected to the write word line WL1.

The writing operation in the semiconductor device 1R according to the comparative example is the same as that in the case (FIG. 7) of the semiconductor device 1 according to the present embodiment excepting disconnection of the fuse 23. That is, information is written into the storage element 21 by applying the stress voltage VST (step S1), breaking down the dielectric film 131 (step S2), and forming the filament F (step S3).

In the semiconductor device 1R according to the comparative example, when there exists a memory cell 20R into which information has already been written (the filament F has been formed) in the same column when the writing operation is to be performed on the memory cell 20R (i, j), such an inconvenience as follows may occur.

FIG. 15 illustrates one example of application of the stress voltage VST to the memory cell 20R (i, j). In this example, information is already written into memory cells 20R (i, j−1) and 20R (i, j+1) in the same column as that of the memory cell 20R (i, j) to be subjected to the writing operation.

When the stress voltage VST is to be applied to the memory cell 20R (i, j), the write word line drive section 11 sets the voltage VWL(j) of the j-th write word line WL1(j) to the negative voltage VM and the bit line drive section 12 sets the voltage VBL (i) of the i-th bit line BL (i) to the positive voltage VP as in the case of the present embodiment. At that time, since the dielectric film 131 of the storage element 21 is broken down in the memory cell 20R (i, j−1), the current I1 flows from the bit line BL (i) to the write word line WL1 (j−1) through the drain of the storage element 21. Since the dielectric film 131 of the storage element 21 is broken down in the memory cell 20R (i, j+1), the current I1 flows from the bit line BL (i) to the write word line WL1 (j+1) through the drain of the storage element 21 similarly. Thus, a voltage drop occurs due to flowing of the current I1, wiring resistance and so forth in the bit line BL (i), a voltage VD (i, j) of the drain of the storage element 21 in the memory cell 20R (i, j) to be subjected to the writing operation drops to a voltage VP2 (VP2<VP) which is lower than the voltage VP to be originally applied. In this case, since also the voltage between the drain and the gate of that storage element 21 drops to a voltage (VP2+|VM|) which is lower than the stress voltage VST (VP+|VM|) to be originally applied, breakdown of the dielectric film 131 or formation of the filament F may not be allowed.

Such an inconvenience becomes more remarkable as the memory cell 20R to be subjected to the writing operation more goes away from the bit line drive section 12, and also becomes more remarkable as more memory cells 20R into which the information has already been written are present in the same column as that of the memory cell 20R (i, j) to be subjected to the writing operation. Therefore, in the semiconductor device 1R, it becomes necessary to set again the voltage VP in consideration of this voltage drop so as to surely perform the writing operation under any condition.

In addition in this example, since a large current flows into the bit line BL (i), it becomes necessary to use such a large transistor as to allow flowing of such a large current as the transistor for driving the bit line BL (i). That is, the macro-size of the entire semiconductor device 1 may be increased due to an increase in size of the bit line drive section 12.

In addition, in the semiconductor device 1R according to the comparative example, such an inconvenience as follows may occur in the memory cell 20R in the same column when performing the reading operation on the memory cell 20R (i, j).

FIG. 16 illustrates one example of the reading operation to be performed on the memory cell 20R (i, j). When information is to be read out from the memory cell 20R (i, j), the read word line drive section 11 sets the voltage VWL2 (j) of the j-th read word line WL2 (j) to the high level voltage VH and the sense amplifier 14 sets the voltage VSL (i) of the i-th source line SL (i) to the positive voltage Vread as in the case in the present embodiment. At that time, currents flow into the memory cell 20R (i, j) through two channels. That is, a current I2 flows from the source line SL (i) to the bit line BL (i) through the selecting transistor 22 and the storage element 21 (the filament F) and a current I3 flows from the source line SL (i) also to the write word line WL1 (j) through the selecting transistor 22 and the storage element 21 (the filament F). In the write word line WL1 (j), a voltage drop occurs due to flowing of the current I3, wiring resistance and so forth, voltages VG of the gates of the storage elements 21 of other memory cells 20R (for example, memory cells 20R (i−1, J), 20R (j+1, j) and so forth) that belong to the same row as the above rise from 0V and the storage elements 21 enter the ON states, and thus the reading operation may become unstable.

Such an inconvenience becomes more remarkable as the memory cell 20R to be subjected to the reading operation more goes away from the write word line drive section 11. Therefore, it becomes necessary to design a peripheral circuit such as the write word line drive section 11 or the like in consideration of the amount corresponding to this voltage drop so as to stably perform the reading operation under any condition in the semiconductor device 1R.

On the other hand, since the semiconductor device 1 according to the present embodiment disposes the fuse 23 on each memory cell 20, it is allowed to reduce the possibility of occurrence of such inconveniences as those in the comparative example even when there exists the memory cell 20 into which the information has already been written in the same column as that of the memory cell 20 to be subjected to the writing operation, as described below.

FIG. 17 illustrates one example of application of the stress voltage VST to the memory cell 20 (i, j) according to the present embodiment. FIG. 17 corresponds to FIG. 15 for the semiconductor device 1R according to the comparative example. The dielectric films 131 of the storage elements 21 are broken down in memory cells 20 (i, j−1) and 20 (i, j+1) as in the case of the comparative example. However, since the fuses 23 are in the open-circuited states in these memory cells 20 (i, j−1) and 20 (i, j+1), no current flows from the bit line BL (i) to the write word lines WL1 (j−1) and WL1 (J+1) unlike the case of the comparative example. Therefore, it is allowed to reduce the possibility of occurrence of the voltage drop in the bit line BL (i) and it is also allowed to reduce the possibility that the writing operation to be performed on the memory cell 20 (i, j) may become unstable.

In addition, since it is allowed to reduce the possibility of flowing of a large current into the bit line BL (i) unlike the case of the comparative example (FIG. 15), it is allowed to reduce the size of the transistor for driving the bit line BL (i). Thus, since it is allowed to miniaturize the peripheral circuit such as the bit line drive section or the like, it is allowed to reduce the macro-size of the entire semiconductor device 1.

In addition, it is allowed to reduce the possibility of occurrence of such an inconvenience that would occur in the comparative example even when the reading operation is performed on the memory cell 20 (i, j) in the semiconductor device 1 according to the present embodiment. That is, since the fuse 23 of the memory cell 20 (i, j) to be subjected to the reading operation is in the open-circuited state as illustrated in FIG. 13, no current flows from the source line SL (i) to the write word line WL1 (j) unlike the case (FIG. 16) of the comparative example. Therefore, since it is allowed to reduce the possibility of occurrence of the voltage drop in the write word line WL1 (j), it is allowed to put the storage element 21 of the memory cell 20 that belongs to the same row as the memory cell 20 (i, j) into an OFF state and therefore it is allowed to reduce the possibility that the reading operation may become unstable.

### [Effects]

Since the present embodiment is configured such that the fuse is disposed on the gate of the storage element as described above and therefore it is allowed to miniaturize the peripheral circuit such as the bit line drive section or the like, it is allowed to reduce the macro-size of the entire semiconductor device.

Since the present embodiment is configured such that the fuse is formed by the narrowed part of the conductive film 132, it is allowed to simplify the configuration, it is allowed to implement the fuse with small area, and therefore it is allowed to suppress an increase in macro-size of the entire semiconductor device.

Since the present embodiment is configured such that the storage element and the selecting transistor share the semiconductor layer 112N, it is allowed to reduce the size of the memory cell.

Since the present embodiment is configured such that the fuse in the memory cell into which the information has been written is disconnected, it is allowed to reduce the possibility that the writing operation may become unstable even when there exists the memory cell into which the information has already been written in the same column as that of the memory cell to be subjected to the writing operation. In addition, since even when information has already been written into the memory cell to be subjected to the reading operation, it is allowed to put the storage element of the memory cell that belongs to the same row as that of the memory cell into the OFF state, it is allowed to reduce the possibility that the reading operation may become unstable.

### Modification Example 1

Although the parts of the respective semiconductor layers 111N, 112N, and 113N are silicided in the above-mentioned embodiment, the present disclosure is not limited to this and the parts may not be silicided, for example, as illustrated in FIG. 18 in place of the above. In this case, the filament F may be formed by melting the parts of the respective electrodes 141 and 142, for example by application of the stress voltage VST.

### Modification Example 2

Although the storage element 21 and the selecting transistor 22 share the semiconductor layer 112N in the above-mentioned embodiment, the present disclosure is not limited to this, and the storage element 21 and the selecting transistor 22 may be separately configured, for example, as illustrated in FIG. 19 in place of the above. In this example, the semiconductor layer 111N, a semiconductor layer 212N, the dielectric film 131, and the conductive film 132 configure the storage element 21, and a semiconductor layer 312N, the semiconductor layer 113N, the dielectric film 131, and the conductive film 134 configure the selecting transistor 22. Thus, it is allowed to further increase the degree of freedom in layout of the memory cell 20. Specifically, for example, when there is a possibility that the characteristic of the selecting transistor may be changed with heat generated when the fuse 23 (the narrowed part 160 in FIG. 5) is disconnected, they may be arranged separately from each other.

### Modification Example 3

Although the fuse 23 is configured as the narrowed part 160 of the conductive film 132 as illustrated in FIG. 5 in the above-mentioned embodiment, the present disclosure is not limited to this. The fuse may be configured as a narrowed part 160C of a wiring 155C which is connected with a conductive film 132C via the contact 145, for example, as illustrated in FIG. 20, or it may be configured by a contact 145D which is smaller in sectional area than a general contact (for example, the contact 144) as illustrated in FIG. 21. In addition, a narrowed part 160E may be formed on a contact 145E as illustrated in FIG. 22.

### 2. Application Example

An application example of the semiconductor device described in any of the above-mentioned embodiment and modification examples will be described.

FIG. 23 illustrates one example of an outer appearance of a television set to which the semiconductor device according to any of the above-mentioned embodiment and the like is applied. The television set may include, for example, an image display screen section 510 including a front panel 511 and filter glass 512.

It is allowed to apply the semiconductor device according to any of the above-mentioned embodiment and the like to an electronic apparatus in any field including a digital camera, a notebook personal computer, a mobile terminal device such as a mobile phone and so forth, a handheld game console, a video camera and so forth in addition to such a television set. Specifically, it is allowed to apply the semiconductor device of any of the above-mentioned embodiment and the like to semiconductor devices built in such various kinds of electronic apparatus.

Although the present disclosure has been described by giving the example embodiment and modification examples and the examples applied to the electronic apparatus hereinabove, the present disclosure is not limited to these embodiment and modification examples and the application example and may be modified in a variety of ways.

Although, for example, the storage is configured by using the storage element 21 and the fuse 23 in the above-mentioned embodiment, the present disclosure is not limited to this and the storage element 21 and the fuse 23 may be used as a switch configured to be settable only one time, for example, as illustrated in FIG. 24. In this example, the storage element 21 and the fuse 23 are applied to a circuit (a delay adjustment circuit) adapted to adjust a delay amount of a signal. Specifically, when the filament F is not formed on a storage element 94, a signal input from a buffer 91 is supplied to a buffer 93 via a delay circuit 92. On the other hand, when the filament is formed on the storage element 94, the signal input from the buffer 91 is supplied to the buffer 93 via the filament of the storage element 94 in place of the delay circuit 92. When the filament is to be formed on the storage element 94, a write circuit 96 applies the stress voltage VST between a drain and a gate of the storage element 94 as in the case of the above-mentioned embodiment.

In addition, for example, although the storage element 21 has been described as the element having the same configuration as the N type MOS transistor, in the above-mentioned embodiment, the storage element is not limited to the above and may have the same configuration, for example, as a P type MOS transistor in place of the above. In that case, the dielectric film is broken down to form the filament F by applying a positive voltage to the gate of the storage element and applying a negative voltage to the drain or source thereof with no generation of the inversion layer on the semiconductor layer under the gate when the writing operation is to be performed.

In addition, for example, although the storage element 21 has been described as the element having the same configuration as the MOS transistor, in the above-mentioned embodiment, the present disclosure is not limited to the above and the storage element of any configuration may be used as long as it is of the type that it includes three or more terminals and the state between the first terminal and the second terminal is changed from the high resistance state into the low resistance state and the state between the second terminal and the third terminal is changed from the open-circuited state (the non-conductive state) into the short-circuited state (the conductive state) accordingly by applying the stress voltage VST between the first terminal and the second terminal Specifically, the storage element may be, for example, an FET (Field Effect Transistor) and/or a bipolar transistor having such a function as mentioned above.

Furthermore, the technology encompasses any possible combination of some or all of the various embodiments described herein and incorporated herein.

It is possible to achieve at least the following configurations from the above-described example embodiments of the disclosure.

(1) A semiconductor device, including:

a storage element including a first terminal, a second terminal, and a third terminal, and in which a resistance state between the second terminal and the third terminal is changed from a high resistance state to a low resistance state based on a stress current that flows between the first terminal and the second terminal; and

a fuse connected to the first terminal, and configured to change from a conductive state to a non-conductive state based on the stress current.

(2) The semiconductor device according to (1), wherein the storage element includes:

a first semiconductor layer of a first conductivity type;

a second semiconductor layer of a second conductivity type connected to the second terminal, and selectively provided on a front surface side within the first semiconductor layer;

a third semiconductor layer of the second conductivity type connected to the third terminal, and selectively provided, away from the second semiconductor layer, on the front surface side within the first semiconductor layer;

a dielectric film provided on a front surface of the first semiconductor layer between the second semiconductor layer and the third semiconductor layer; and

a conductive film connected to the first terminal, and provided on the dielectric film.

(3) The semiconductor device according to (2), wherein

the stress current is generated by breakdown of the dielectric film by application of a stress voltage between the first terminal and the second terminal, and

the resistance state is changed from the high resistance state to the low resistance state, by formation of a filament between the second semiconductor layer and the third semiconductor layer resulting from heat generated by the stress current.

(4) The semiconductor device according to (3), wherein

a part of the second semiconductor layer is silicided, and

the filament is a molten part of the silicided part of the second semiconductor layer.

(5) The semiconductor device according to (3) or (4), wherein

the storage element includes an electrode provided on a part of the second semiconductor layer, and

the filament is a molten part of the electrode.

(6) The semiconductor device according to any one of (3) to (5), wherein the fuse changes from the conductive state to the non-conductive state after the formation of the filament.
(7) The semiconductor device according to any one of (3) to (6), wherein the stress current has a current value that is equal to or higher than a minimum current value necessary for the formation of the filament.
(8) The semiconductor device according to any one of (3) to (7), wherein the stress voltage has a polarity that is reverse to a polarity of a voltage that generates an inversion layer in the first semiconductor layer between the second semiconductor layer and the third semiconductor layer.
(9) The semiconductor device according to any one of (2) to (8), wherein

the dielectric film and the conductive film each extend from a region sandwiched between the second semiconductor layer and the third semiconductor layer up to a region adjacent to the sandwiched region,

the conductive film includes a narrowed part in the adjacent region, and

the narrowed part configures the fuse.

(10) The semiconductor device according to any one of (2) to (8), further including a wiring led to the conductive film and having a narrowed part that configures the fuse.
(11) The semiconductor device according to any one of (2) to (8), further including a contact,

wherein the dielectric film and the conductive film each extend from a region sandwiched between the second semiconductor layer and the third semiconductor layer up to a region adjacent to the sandwiched region, and

the contact is provided on the conductive film in a part of the adjacent region, and configures the fuse.

(12) A semiconductor device, including:

a plurality of memory cells; and

a control circuit configured to control the plurality of memory cells,

each of the memory cells including
a storage element including a first terminal, a second terminal, and a third terminal, and in which a resistance state between the second terminal and the third terminal is changed from a high resistance state to a low resistance state based on a stress current that flows between the first terminal and the second terminal,
a fuse connected to the first terminal, and configured to change from a conductive state to a non-conductive state based on the stress current, and
a selecting transistor connected to the third terminal
   (13) The semiconductor device according to (12), further including:

a first semiconductor layer of a first conductivity type;

a second semiconductor layer of a second conductivity type connected to the second terminal, and selectively provided on a front surface side within the first semiconductor layer;

a third semiconductor layer of the second conductivity type connected to the third terminal, and selectively provided, away from the second semiconductor layer, on the front surface side within the first semiconductor layer;

a first dielectric film provided on a front surface of the first semiconductor layer between the second semiconductor layer and the third semiconductor layer;

a first conductive film connected to the first terminal, and provided on the first dielectric film;

a fourth semiconductor layer of the second conductivity type selectively provided, away from the third semiconductor layer, on the front surface side within the first semiconductor layer;

a second dielectric film provided on the front surface of the first semiconductor layer between the third semiconductor layer and the fourth semiconductor layer; and

a second conductive film provided on the second dielectric film,

wherein the second semiconductor layer, the third semiconductor layer, the first dielectric film, and the first conductive film configure the storage element, and

wherein the third semiconductor layer, the fourth semiconductor layer, the second dielectric film, and the second conductive film configure the selecting transistor.

(14) The semiconductor device according to (13), wherein an interval between the second semiconductor layer and the third semiconductor layer is narrower than an interval between the third semiconductor layer and the fourth semiconductor layer.
(15) The semiconductor device according to (12) or (13), wherein

the fuse includes a primary terminal connected to the first terminal and a secondary terminal that is different from the primary terminal, and

the control circuit controls to break down the first dielectric film to generate the stress current by applying a voltage having a first polarity to the second terminal of the storage element and a voltage having a second polarity to the secondary terminal of the fuse.

(16) An electronic apparatus, including:

a storage element including a first terminal, a second terminal, and a third terminal, and in which a resistance state between the second terminal and the third terminal is changed from a high resistance state to a low resistance state based on a stress current that flows between the first terminal and the second terminal;

a fuse connected to the first terminal, and configured to change from a conductive state to a non-conductive state based on the stress current; and

a control circuit configured to control the storage element and the fuse.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device, comprising:
a storage element including a first terminal, a second terminal, and a third terminal, and in which a resistance state between the second terminal and the third terminal is changed from a high resistance state to a low resistance state based on a stress current that flows between the first terminal and the second terminal; and
a fuse connected to the first terminal, and configured to change from a conductive state to a non-conductive state based on the stress current.

2. The semiconductor device according to claim 1, wherein the storage element includes:
a first semiconductor layer of a first conductivity type;
a second semiconductor layer of a second conductivity type connected to the second terminal, and selectively provided on a front surface side within the first semiconductor layer;
a third semiconductor layer of the second conductivity type connected to the third terminal, and selectively provided, away from the second semiconductor layer, on the front surface side within the first semiconductor layer;
a dielectric film provided on a front surface of the first semiconductor layer between the second semiconductor layer and the third semiconductor layer; and
a conductive film connected to the first terminal, and provided on the dielectric film.

3. The semiconductor device according to claim 2, wherein
the stress current is generated by breakdown of the dielectric film by application of a stress voltage between the first terminal and the second terminal, and
the resistance state is changed from the high resistance state to the low resistance state, by formation of a filament between the second semiconductor layer and the third semiconductor layer resulting from heat generated by the stress current.

4. The semiconductor device according to claim 3, wherein
a part of the second semiconductor layer is silicided, and
the filament is a molten part of the silicided part of the second semiconductor layer.

5. The semiconductor device according to claim 3, wherein
the storage element includes an electrode provided on a part of the second semiconductor layer, and
the filament is a molten part of the electrode.

6. The semiconductor device according to claim 3, wherein the fuse changes from the conductive state to the non-conductive state after the formation of the filament.

7. The semiconductor device according to claim 3, wherein the stress current has a current value that is equal to or higher than a minimum current value necessary for the formation of the filament.

8. The semiconductor device according to claim 3, wherein the stress voltage has a polarity that is reverse to a polarity of a voltage that generates an inversion layer in the first semiconductor layer between the second semiconductor layer and the third semiconductor layer.

9. The semiconductor device according to claim 2, wherein
the dielectric film and the conductive film each extend from a region sandwiched between the second semiconductor layer and the third semiconductor layer up to a region adjacent to the sandwiched region,
the conductive film includes a narrowed part in the adjacent region, and
the narrowed part configures the fuse.

10. The semiconductor device according to claim 2, further comprising a wiring led to the conductive film and having a narrowed part that configures the fuse.

11. The semiconductor device according to claim 2, further comprising a contact,
wherein the dielectric film and the conductive film each extend from a region sandwiched between the second semiconductor layer and the third semiconductor layer up to a region adjacent to the sandwiched region, and
the contact is provided on the conductive film in a part of the adjacent region, and configures the fuse.

12. A semiconductor device, comprising:
a plurality of memory cells; and
a control circuit configured to control the plurality of memory cells,
each of the memory cells including
a storage element including a first terminal, a second terminal, and a third terminal, and in which a resistance state between the second terminal and the third terminal is changed from a high resistance state to a low resistance state based on a stress current that flows between the first terminal and the second terminal,
a fuse connected to the first terminal, and configured to change from a conductive state to a non-conductive state based on the stress current, and
a selecting transistor connected to the third terminal.

13. The semiconductor device according to claim 12, further comprising:
a first semiconductor layer of a first conductivity type;
a second semiconductor layer of a second conductivity type connected to the second terminal, and selectively provided on a front surface side within the first semiconductor layer;
a third semiconductor layer of the second conductivity type connected to the third terminal, and selectively provided, away from the second semiconductor layer, on the front surface side within the first semiconductor layer;
a first dielectric film provided on a front surface of the first semiconductor layer between the second semiconductor layer and the third semiconductor layer;
a first conductive film connected to the first terminal, and provided on the first dielectric film;
a fourth semiconductor layer of the second conductivity type selectively provided, away from the third semiconductor layer, on the front surface side within the first semiconductor layer;
a second dielectric film provided on the front surface of the first semiconductor layer between the third semiconductor layer and the fourth semiconductor layer; and
a second conductive film provided on the second dielectric film,
wherein the second semiconductor layer, the third semiconductor layer, the first dielectric film, and the first conductive film configure the storage element, and
wherein the third semiconductor layer, the fourth semiconductor layer, the second dielectric film, and the second conductive film configure the selecting transistor.

14. The semiconductor device according to claim 13, wherein an interval between the second semiconductor layer and the third semiconductor layer is narrower than an interval between the third semiconductor layer and the fourth semiconductor layer.

15. The semiconductor device according to claim 12, wherein
the fuse includes a primary terminal connected to the first terminal and a secondary terminal that is different from the primary terminal, and
the control circuit controls to break down the first dielectric film to generate the stress current by applying a voltage having a first polarity to the second terminal of the storage element and a voltage having a second polarity to the secondary terminal of the fuse.

16. An electronic apparatus, comprising:
a storage element including a first terminal, a second terminal, and a third terminal, and in which a resistance state between the second terminal and the third terminal is changed from a high resistance state to a low resistance state based on a stress current that flows between the first terminal and the second terminal;
a fuse connected to the first terminal, and configured to change from a conductive state to a non-conductive state based on the stress current; and
a control circuit configured to control the storage element and the fuse.
